(19) United States
(12) Patent Application Publication
(10) Pub. No.: US 2009/0188551 A1
(43) Pub. Date: Jul. 30, 2009

(54) SOLAR CELL AND METHOD OF MANUFACTURING THE SAME

(76) Inventor: Tae-Hyung HWANG, Seoul (KR)

Correspondence Address: Haynes and Boone, LLP;IP Section, 2323 Victory Avenue, SUITE 700, Dallas, TX, 75219, US

(21) Appl. No.: 12/189,575

(22) Filed: Aug. 11, 2008

(30) Foreign Application Priority Data
Jan. 25, 2008 (KR) 10-2008-0008138

(51) Int. Cl. H01L 31/0232; H01L 31/00

(52) U.S. Cl. 136/255; 136/256; 438/72; 257/E31.127

(57) ABSTRACT

A solar cell is provided. The solar cell includes: a substrate; a first electrode that is formed on the substrate; a second electrode that is formed on the substrate and that is apart from the first electrode; and a photoelectric conversion element with one side connected to the first electrode and the other side connected to the second electrode, wherein an area that the photoelectric conversion element occupies is 30% or less of that of the substrate. Therefore, because an occupying area of an inorganic film is very small in a solar cell of a solar panel, the solar panel can have flexibility.

### CROSS-REFERENCE TO RELATED APPLICATION

This application claims priority to, and the benefit of, Korean Patent Application No. 10-2008-0008138 filed in the Korean Intellectual Property Office on Jan. 25, 2008, the entire contents of which are incorporated herein by reference.

### BACKGROUND OF THE INVENTION

(a) Field of the Invention

The present invention relates to a solar cell.

(b) Description of the Related Art

A solar cell is a cell that generates electrical energy from solar energy, is environmental-friendly, and as it draws energy from the sun, has an effectively infinite energy source and a long lifetime. The solar cells are largely categorized as a crystalline silicon solar cell that is used in most commercial products, a thin film solar cell that can use an inexpensive substrate, and a hybrid solar cell with elements of both the crystalline silicon solar cell and the thin film solar cell.

The crystalline silicon solar cell uses a silicon slice in which a silicon lump is thinly cut for a substrate, and is categorized as a monocrystalline solar cell or a polycrystalline solar cell according to a method of manufacturing the silicon. The crystalline silicon solar cell, for example the monocrystalline solar cell, has a p-n junction structure typically consisting of an n-type semiconductor (in which a pentavalent element such as phosphorus, arsenic, or antimony is added to silicon), and a p-type semiconductor (that is formed by doping a trivalent element such as boron or potassium into silicon), where the p-n junction structure is substantially identical to that of a diode. The thickness of the crystalline silicon solar cell is typically about 200 μm to 300 μm.

The thin film solar cell is typically formed by coating a film on a thin glass or plastic substrate. Typical examples of thin film solar cells include, for example, an amorphous silicon solar cell, a copper-indium-selenium (CuInSe2) solar cell, a cadmium-tellurium (CdTe) solar cell, and a dye-sensitized solar cell. In general, a thin film solar cell uses glass as a substrate, and includes a rear electrode, an optical absorption layer, a p-n junction layer, a buffer layer, a front transparent electrode, and a reflection prevention film that are formed thereon. The buffer layer is formed between the p-type semiconductor and the n-type semiconductor of the p-n junction layer in order to well-couple the p-type and n-type semiconductors, and the thickness of the thin film solar cell is less than 1/100 of that of the crystalline silicon solar cell.

A solar cell may have a structure including an inorganic film such as silicon or a compound semiconductor. However, if such a solar cell is bent even a little, because the inorganic film is easily damaged, performance thereof may be deteriorated.

### SUMMARY OF THE INVENTION

An exemplary embodiment of the present invention provides a solar cell including: a substrate; a first electrode that is formed on the substrate; a second electrode that is formed on the substrate and that is apart from the first electrode; a photoelectric conversion element with one side connected to the first electrode and the other side connected to the second electrode; and a reflective layer that is positioned between the substrate and the photoelectric conversion element.

The reflective layer may include at least one recess portion.

The solar cell may further include a reflector that is formed in the recess portion.

The first electrode, the second electrode, and the reflector may be made of an identical material.

The solar cell may further include a focusing layer that is formed on the first electrode, the second electrode, and the photoelectric conversion element. The focusing layer may be made of an organic material.

The first electrode and the second electrode may be positioned at the same layer.

The solar cell may further include a connector that connects the photoelectric conversion element to the second electrode.

The photoelectric conversion element may be partially overlapped with the first electrode and may be positioned at the same layer as that of the first electrode.

The connector may be made of indium tin oxide (ITO) or indium zinc oxide (IZO).

The reflective layer may include an organic material.

The substrate may include glass, plastic, metal, or a polymer.

The photoelectric conversion element may include a p-type semiconductor layer, an n-type semiconductor layer, and an intrinsic semiconductor layer that is positioned between the p-type semiconductor layer and the n-type semiconductor layer.

The intrinsic semiconductor layer may include amorphous silicon, and the p-type semiconductor layer and the n-type semiconductor layer may include amorphous silicon in which an impurity is doped with a high concentration.

Another embodiment of the present invention provides a solar cell including: a substrate; a first electrode that is formed on the substrate; a second electrode that is formed on the substrate and that is apart from the first electrode; and a photoelectric conversion element with one side connected to the first electrode and the other side connected to the second electrode, wherein the photoelectric conversion element occupies less than or equal to 30% of an area of the substrate.

Yet another embodiment of the present invention provides a solar cell including: a substrate; a first electrode line that is formed on the substrate; a second electrode line that is formed on the substrate and that is apart from the first electrode line; a plurality of photoelectric conversion elements that are connected to the first electrode line and the second electrode line; and a plurality of reflective members that are formed between the plurality of photoelectric conversion elements.

The solar cell may further include a focusing layer that is formed on the first and second electrode lines, the plurality of photoelectric conversion elements, and the plurality of reflective members.

An area that the plurality of photoelectric conversion elements occupy may be 30% or less of that of the substrate.

A further embodiment of the present invention provides a method of manufacturing a solar cell including: forming a reflective layer having a recessed portion on a substrate; stacking a metal film on the reflective layer; forming a reflector on the recessed portion while forming a first electrode and a second electrode by etching the metal film; forming a photoelectric conversion element that is apart from the second electrode while contacting the first electrode; and forming a connector that connects the photoelectric conversion element and the second electrode.

The method may further include forming a focusing layer on the photoelectric conversion element and the connector.

The recess portion and the focusing layer may be formed using an imprint process or a photolithography process.

An area that the photoelectric conversion element occupies may be 30% or less of that of the substrate.

The photoelectric conversion element may be formed using a photolithography process.

According to an exemplary embodiment of the present invention, because an area that an inorganic film occupies is very small in a solar cell of a solar panel, the solar panel can have flexibility. Therefore, even if the solar cell is bent, it is not easily damaged and is variously formed, the establishment of the solar panel is easily.

In addition, because the solar panel according to an exemplary embodiment of the present invention can be manufactured in a roll-to-roll manner, a process of manufacturing the solar panel is simple and productivity can be improved. Therefore, the production cost of the solar panel can be reduced.

### BRIEF DESCRIPTION OF THE DRAWINGS

An exemplary embodiment of the present invention will be described in detail with reference to the accompanying drawings for clear understanding of advantages of the present invention, wherein:

FIG. 1 is a top plan view of a solar panel according to an exemplary embodiment of the present invention;

FIG. 2 is an equivalent circuit diagram of the solar panel that is shown in FIG. 1;

FIG. 3 is an enlarged view of a solar cell that is shown in FIG. 1;

FIG. 4 is a cross-sectional view of the solar cell that is taken along line IV-IV of FIG. 3;

FIG. 5 is a cross-sectional view of the solar cell that is taken along line V-V of FIG. 3;

FIG. 6 is a detailed view of a photoelectric conversion element in the solar cell that is shown in FIG. 3;

FIG. 7 is a cross-sectional view of a solar cell according to another exemplary embodiment of the present invention; and

FIG. 8 is a cross-sectional view of the solar cell that is taken along lines VIIIa-VIIIa and VIIIb-VIIIb of FIG. 7;

FIGS. 9 to 11 are cross-sectional views illustrating a method of manufacturing a solar cell according to an exemplary embodiment of the present invention.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

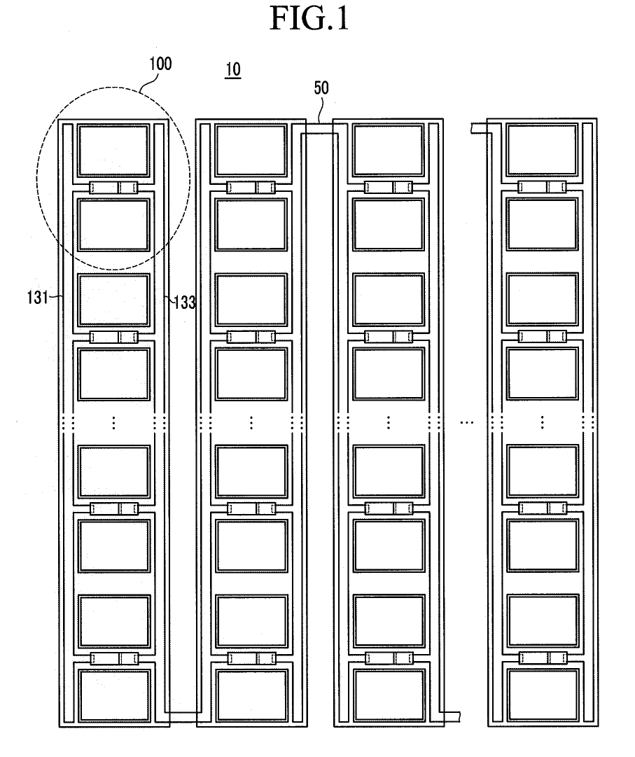

A solar cell according to an exemplary embodiment of the present invention is described with reference to FIGS. 1 to 5.

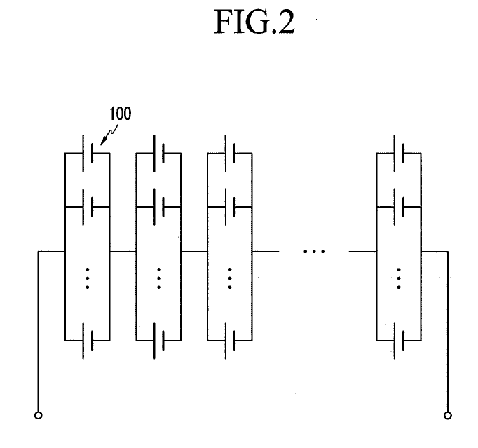

FIG. 1 is a top plan view of a solar panel according to an exemplary embodiment of the present invention, and FIG. 2 is an equivalent circuit diagram of the solar panel shown in FIG. 1.

Referring to FIG. 1, a solar panel 10 includes a plurality of solar cells 100, a plurality of first electrode lines 131, a plurality of second electrode lines 133, and a plurality of connection lines 50.

The plurality of solar cells 100 are arranged in a matrix form, and the first electrode line 131 and the second electrode line 133 are positioned at the left and right sides of each column of each solar cell 100, respectively. The first electrode line 131 and second electrode line 133 extend in a direction generally along a column of the solar cells 100. The solar cells 100 of each column are electrically connected in parallel through the second electrode line 132 and the first electrode line 131. Furthermore, the adjacent first electrode line 131 and second electrode line 133 are connected through the connection line 50. Thus, columns of the solar cells 100 are connected in series (see FIG. 2). When the solar cells 100 are connected in this combination of series and parallel, a desired magnitude of voltage and current can be more easily obtained. When the solar cells 100 are connected in series, a voltage generated increases, and when the solar cells 100 are connected in parallel, a voltage thereof does not increase but a magnitude of current generated increases. Alternatively, the solar cells 100 may be connected only in series or only in parallel. The solar panel 10 may include any one or more solar cells 100.

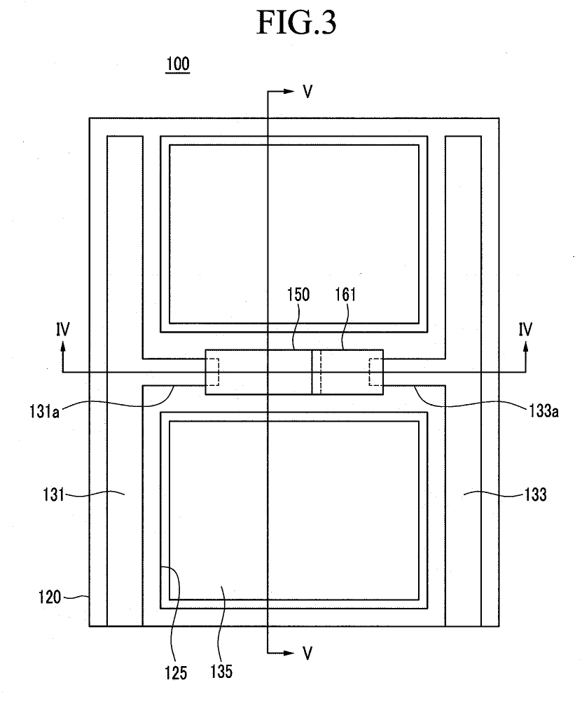

A solar cell 100 according to an exemplary embodiment of the present invention is described in detail with reference to FIGS. 3 to 6.

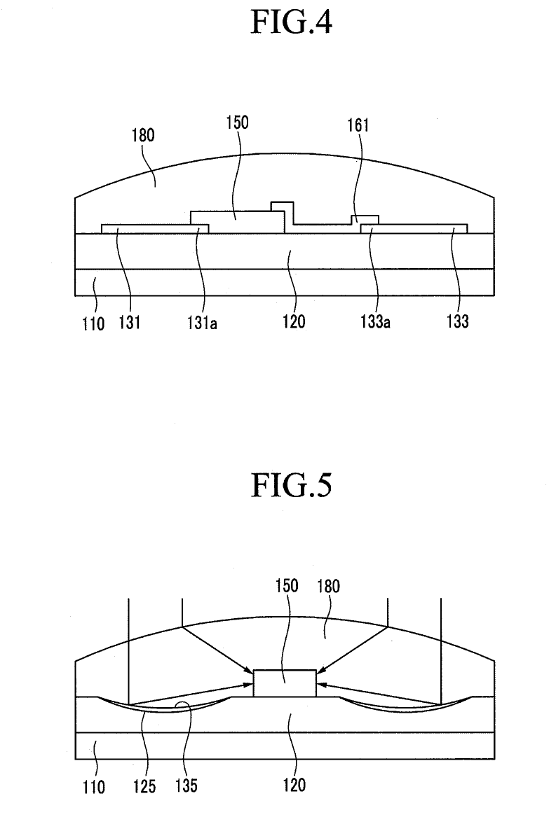

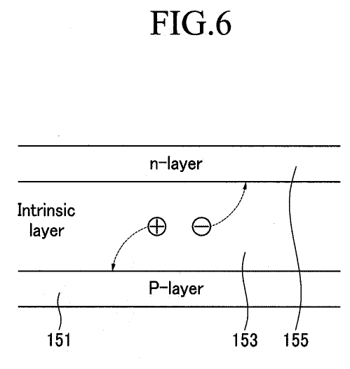

FIG. 3 is an enlarged view of a solar cell that is shown in FIG. 1. FIG. 4 is a cross-sectional view of the solar cell that is taken along line IV-IV of FIG. 3. FIG. 5 is a cross-sectional view of the solar cell that is taken along line V-V of FIG. 3, and FIG. 6 is a detailed view of a photoelectric conversion element in the solar cell that is shown in FIG. 3.

Referring to FIGS. 3 to 6, a reflective layer 120 is formed on a flexible substrate 110 that is made of glass, plastic, metal, or a polymer.

The reflective layer 120 is made of an organic insulating material and has a pair of recessed portions 125 that are arranged along a column. The recessed portion 125 becomes gradually deeper toward the center, a cross-section thereof has an approximate half-circle or half-oval shape, and a plane thereof has a generally quadrangular shape. A curvature of the recessed portion 125 may vary according to the design, as can the cross-sectional shape and the plane shape. The reflective layer 120 may be made of an insulating material having a reflectivity. The reflective layer 120 may be omitted, in which case a pair of recessed portions may be formed in the substrate 110.

On the reflective layer 120, a first electrode line 131, a second electrode line 133, and a pair of reflectors 135 are formed apart from each other. The first electrode line 131, the second electrode line 133, and the reflector 135 may be made of an identical material, for example a material such as molybdenum (Mo), aluminum (Al), nickel (Ni), and copper (Cu), and particularly of a metal having a reflectivity.

Each of the first electrode line 131 and the second electrode line 133 extends in a column direction at the left and right sides of the corresponding recessed portion 125. The first electrode line 131 includes a first electrode 131a and the second electrode line 133 includes a second electrode 133a. Furthermore, the first electrode 131a and the second electrode 133a are positioned between two reflectors 135 and protrude toward each other.

A photoelectric conversion element 150 and a connector 161 are formed on the reflective layer 120, the first electrode 131a, and the second electrode 133a.

The photoelectric conversion element 150 is positioned on the first electrode 131a and the reflective layer 120, and may be made of an inorganic material such as silicon or a compound semiconductor. However, in a dye-sensitized solar cell or an organic molecule junction type (organic D-A) solar cell, the photoelectric conversion element 150 may be made of an organic material. The connector 161 is positioned on the photoelectric conversion element 150, the second electrode 133a, and the reflective layer 120, and is made of an inorganic film such as ITO or IZO.

As shown in FIG. 6, the photoelectric conversion element 150 is formed in a p-i-n junction configuration. Specifically, the photoelectric conversion element 150 includes a p-type semiconductor layer 151, an n-type semiconductor layer 155, and an intrinsic semiconductor layer 153 that is positioned therebetween. The intrinsic semiconductor layer 153 may be made of amorphous silicon, and the p-type semiconductor layer 151 and the n-type semiconductor layer 155 may be made of amorphous silicon doped with a high concentration of an impurity, for example, of n-type.

The intrinsic semiconductor layer 153 is a space charge layer in which electrons and holes are diffused, and has high resistance, high permittivity, and high capacitance. When photons of sunlight are absorbed into the intrinsic semiconductor layer 153, electron-hole pairs are generated. Due to an electric field of the space charge layer, electrons and holes move in opposite directions and thus negative (−) charges are stacked in the n-type semiconductor layer 155 and positive (+) charges are stacked in the p-type semiconductor layer 151. A current flows when an external circuit is connected thereto.

The photoelectric conversion element 150 may be formed in a p-n junction configuration in which the intrinsic semiconductor layer 153 is omitted. In this case, a space charge layer is formed in a coupling portion of the p-type semiconductor and the n-type semiconductor. Further, the photoelectric conversion element 150 may have a structure in which p-i-n junction structures are overlapped with several layers, and may include a red layer, a green layer, and a blue layer in order to variously absorb wavelengths of sunlight.

The p-type semiconductor layer 151 of the photoelectric conversion element 150 is connected to the lower first electrode 131a, and the n-type semiconductor layer 155 is connected to the lower second electrode 133a through the upper connector 161.

A focusing layer 180 is formed on the photoelectric conversion element 150 and the connector 161. The focusing layer 180 is made of an organic material and has a curved upper surface, so that sunlight may be focused to the photoelectric conversion element 150. Therefore, as shown in FIG. 5, sunlight that is applied to the solar cell 100 is appropriately refracted in the focusing layer 180 to advance toward the photoelectric conversion element 150, and sunlight that does not reach the photoelectric conversion element 150 but reaches the reflective layer 120 is reflected by the reflector 135 to advance toward the photoelectric conversion element 150.

A reflection prevention layer (not shown) may be formed on the focusing layer 180. The reflection prevention layer is generally made of magnesium fluoride (MgF₂), and can reduce reflection loss of sunlight.

The photoelectric conversion element 150, the first electrode 131a, the second electrode 133a, the connector 161, the recessed portions 125, and the reflector 135 constitute a solar cell 100. Therefore, each solar cell 100 has an area that is bounded by the first electrode line 131 and the second electrode line 133 as approximate left and right side borders, an upper recessed portion 125 as an upper border, and a lower recessed portion 125 as a lower border. However, for convenience of description, the total area of one solar cell 100 may be regarded as a value obtained by dividing the entire area including the solar cells 100, the first electrode lines 131, the second electrode lines 133, and gaps therebetween by the number of solar cells 100.

An area that the photoelectric conversion elements 150 occupy of the entire substrate 110 and an area that each photoelectric conversion element 150 occupies in a solar cell 100 may be about 30% or less of the entire substrate 110 or the solar cell 100. An area of the connector 161 is equal to or less than that of the photoelectric conversion element 150.

Because the area occupied by the photoelectric conversion element 150 and the connector 161 is small, even if the solar panel 10 is bent, the photoelectric conversion element 150 and the connector 161 are not likely to be damaged. Accordingly, a solar panel 10 including the solar cells 100 according to the present exemplary embodiment can have flexibility and thus can be produced in a roll-to-roll manner, i.e., continuously produced in a cylindrical shape by rolling. As the solar panel 10 can be produced in a roll-to-roll manner, it can be mass-produced within a short time period and the cost for manufacturing the solar cells 100 can be reduced.

When an organic material and a metal are used for the substrate 110, the reflective layer 120, the first electrode line 131, the second electrode line 133, the reflector 135, and the focusing layer 180, because they have good flexibility, are not easily damaged even if they are bent. For example, in a case where a molybdenum/aluminum/molybdenum alloy was used as a material of the above-described elements, when the alloy was bent 100 times with a curvature radius of 10 mm, the elements' electrical resistance increased about 12%, and when the alloy was bent 100 times with a curvature radius of 20 mm, their resistance was hardly changed.

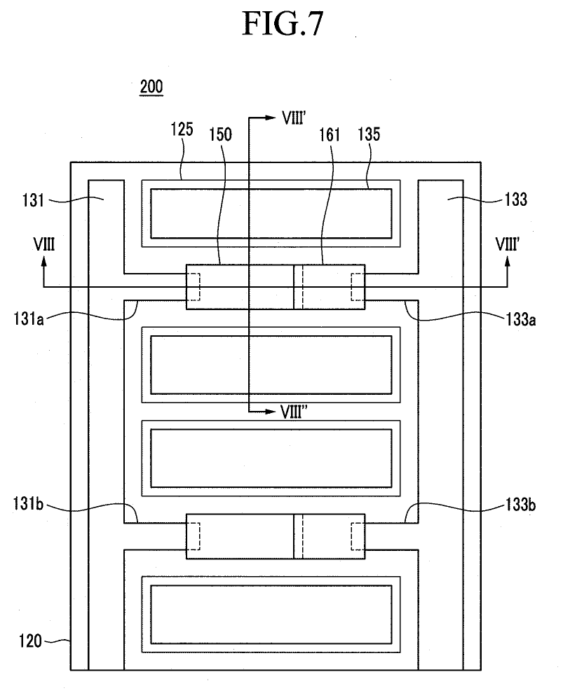

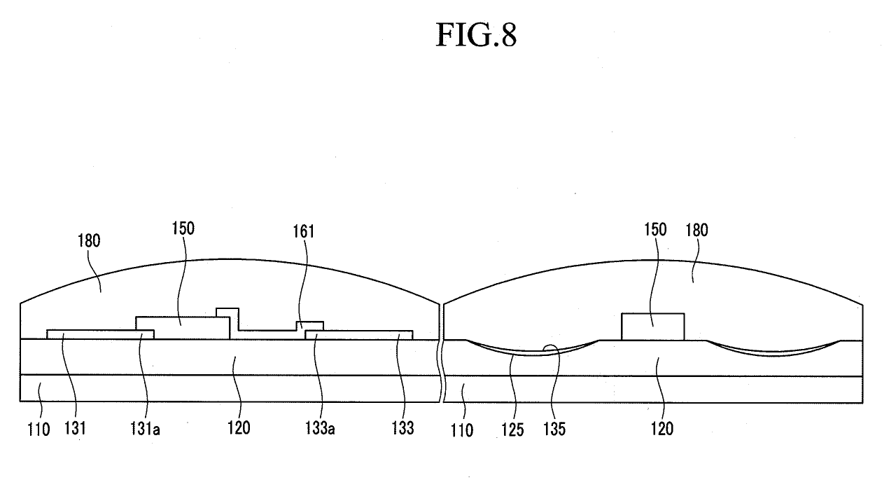

A solar cell according to another exemplary embodiment of the present invention is described with reference to FIGS. 7 and 8.

FIG. 7 is a cross-sectional view of a solar cell according to another exemplary embodiment of the present invention and FIG. 8 is a cross-sectional view of the solar cell that is taken along lines VIIIa-VIIIa and VIIIb-VIIIb of FIG. 7.

Referring to FIGS. 7 and 8, a solar cell 200 according to another exemplary embodiment of the present invention includes first electrodes 131a and 131b, second electrodes 133a and 133b, photoelectric conversion elements 150, connectors 161, and reflectors 135. A structure thereof is substantially identical to that of the exemplary embodiment that is shown in FIGS. 3, 4, and 5.

The solar cell 200 includes two photoelectric conversion elements 150, two connectors 161, two first electrodes 131a and 131b, two second electrodes 133a and 133b, and four reflectors 135 positioned as shown. The reflective layer 120 has four recessed portions 125, and a reflector 135 is disposed at each of the recessed portions 125. Therefore, the reflector 135 and the recessed portions 125 of the reflective layer 120 have an area that is smaller than their areas in FIG. 3. The first electrodes 131a and 131b, the second electrodes 133a and 133b, the photoelectric change elements 150, and the connectors 161 have an area that is identical to their areas shown in FIG. 3. However, they may have smaller areas than those shown in FIG. 3.

The areas of the photoelectric conversion elements 150, the connectors 161, the first electrodes 131a and 131b, the second electrodes 133a and 133b, and the reflectors 135 that are positioned at the solar cell 200 can be variously changed according to the design.

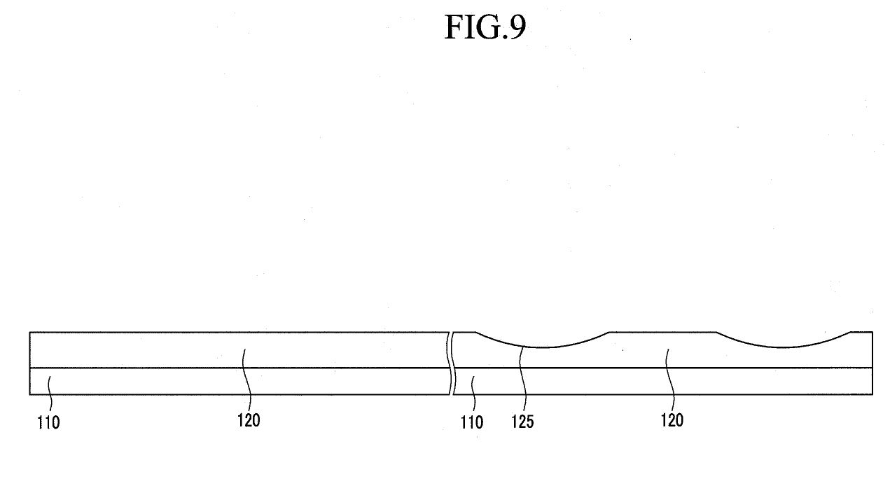

A method of manufacturing a solar cell according to an exemplary embodiment of the present invention is described with reference to FIGS. 9 to 11.

FIGS. 9 to 11 are cross-sectional views sequentially illustrating a process of manufacturing the solar cell of FIG. 7.

First, as shown in FIG. 9, after a reflective layer 120 that is made of organic materials is stacked on a flexible substrate 110 that is made of glass, plastic, metal, or a polymer, recessed portions 125 are formed using an imprint process. The recessed portions 125 may be formed using a photolithography process.

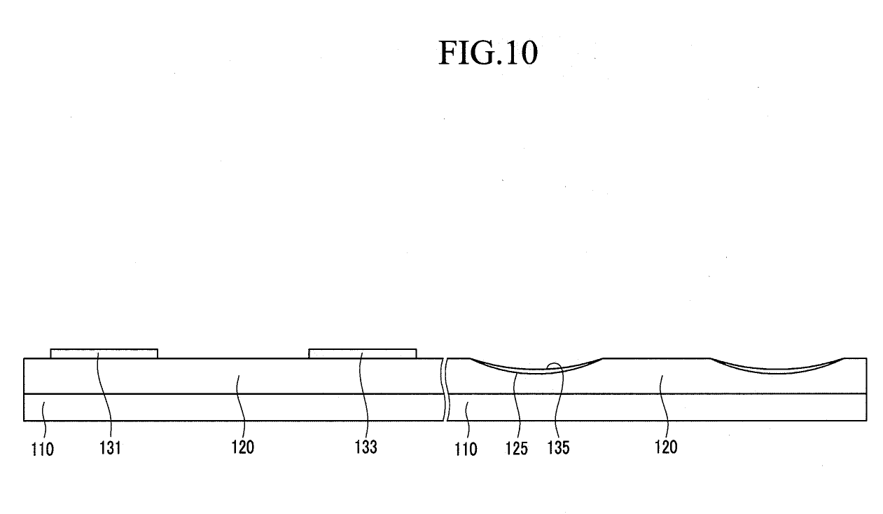

Next, as shown in FIG. 10, after a metal film is stacked on the reflective layer 120, first electrode lines 131, second electrode lines 133, and reflectors 135 are formed by etching the metal film. Each reflector 135 is positioned at the corresponding recessed portion 125, and the first electrode line 131 and the second electrode line 133 are positioned at the left and right sides of the recessed portion 125.

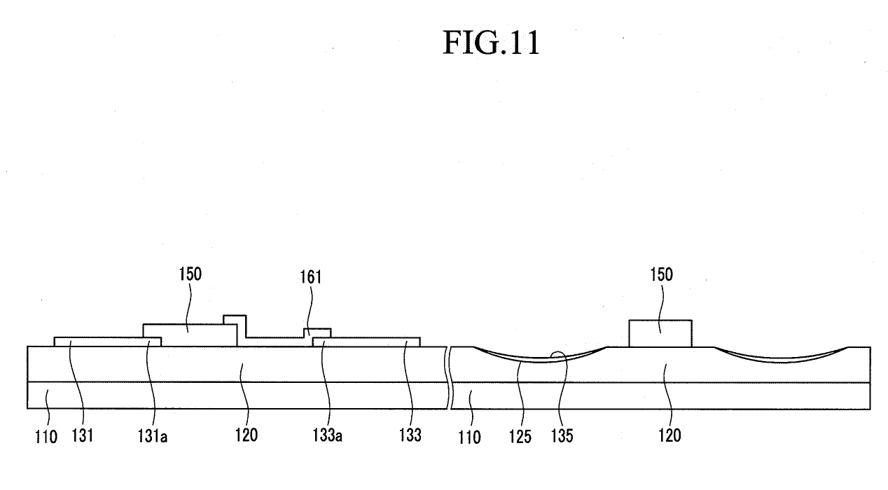

Then, as shown in FIG. 11, after an inorganic material such as silicon or a compound semiconductor is stacked on the first electrodes 131a and the reflective layer 120, photoelectric conversion elements 150 (consisting of a p-type semiconductor layer, an intrinsic semiconductor layer, and an n-type semiconductor layer) are formed by etching the inorganic material. The photoelectric conversion elements 150 have a smaller size than an area of the solar cell. The p-type semiconductor layer of the photoelectric conversion element 150 is connected to the first electrode 131a. Thereafter, after an inorganic film such as ITO or IZO is stacked, connectors 161 that connect the second electrodes 133b and the n-type semiconductor layers of the photoelectric conversion elements 150 are formed by etching the inorganic film. Like the photoelectric conversion element 150, the connector 161 has a size that is much smaller than an area of a solar cell.

Finally, as shown in FIG. 8, a focusing layer 180 that is made of an organic material is formed on the reflective layer 120, the first electrode lines 131, the second electrode lines 133, the photoelectric conversion elements 150, and the connectors 161. A convex curved surface on the focusing layer 180 is formed using an imprint process. The focusing layer 180 may be formed using a photolithography process.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. For example, in the present exemplary embodiment, a liquid crystal display is described, but the present invention can be applied to several display devices including a spacer.

What is claimed is:

1. A solar cell comprising:
a substrate;
a first electrode that is formed on the substrate;
a second electrode that is formed on the substrate and that is apart from the first electrode;
a photoelectric conversion element with one side connected to the first electrode and the other side connected to the second electrode; and
a reflective layer that is positioned between the substrate and the photoelectric conversion element.

2. The solar cell of claim 1, wherein the reflective layer comprises at least one recessed portion.

3. The solar cell of claim 2, further comprising a reflector that is formed in the recessed portion.

4. The solar cell of claim 3, wherein the first electrode, the second electrode, and the reflector are made of the same material.

5. The solar cell of claim 1, further comprising a focusing layer that is formed on the first electrode, the second electrode, and the photoelectric conversion element.

6. The solar cell of claim 5, wherein the focusing layer is made of an organic material.

7. The solar cell of claim 1, wherein the first electrode and the second electrode are positioned at the same layer.

8. The solar cell of claim 7, further comprising a connector that connects the photoelectric conversion element to the second electrode.

9. The solar cell of claim 8, wherein the photoelectric conversion element is partially overlapped with the first electrode and is positioned at the same layer as that of the first electrode.

10. The solar cell of claim 8, wherein the connector is made of ITO or IZO.

11. The solar cell of claim 1, wherein the reflective layer comprises an organic material.

12. The solar cell of claim 1, wherein the substrate comprises glass, plastic, metal, or a polymer.

13. The solar cell of claim 1, wherein the photoelectric conversion element comprises:
a p-type semiconductor layer;
an n-type semiconductor layer; and
an intrinsic semiconductor layer that is positioned between the p-type semiconductor layer and the n-type semiconductor layer.

14. The solar cell of claim 13, wherein the intrinsic semiconductor layer comprises amorphous silicon, and
the p-type semiconductor layer and the n-type semiconductor layer comprise amorphous silicon doped with a high concentration of an impurity.

15. A solar cell comprising:
a substrate;
a first electrode that is formed on the substrate;
a second electrode that is formed on the substrate and that is apart from the first electrode; and
a photoelectric conversion element with one side connected to the first electrode and the other side connected to the second electrode,
wherein the photoelectric conversion element occupies less than or equal to 30% of an area of the substrate.

16. A solar cell comprising:
a substrate;
a first electrode line that is formed on the substrate;
a second electrode line that is formed on the substrate and that is apart from the first electrode line;
a plurality of photoelectric conversion elements that are connected to the first electrode line and the second electrode line; and
a plurality of reflective members that are formed between the plurality of photoelectric conversion elements.

17. The solar cell of claim 16, further comprising a focusing layer that is formed on the first and second electrode lines, the plurality of photoelectric conversion elements, and the plurality of reflective members.

18. The solar cell of claim 16, wherein the plurality of photoelectric conversion elements occupy less than or equal to 30% of an area of the substrate.

19. A method of manufacturing a solar cell, comprising:
forming a reflective layer having a recessed portion on a substrate;
stacking a metal film on the reflective layer;
forming a reflector on the recessed portion while forming a first electrode and a second electrode by etching the metal film;
forming a photoelectric conversion element that is apart from the second electrode while contacting the first electrode; and
forming a connector that connects the photoelectric conversion element and the second electrode.

20. The method of claim 19, further comprising forming a focusing layer on the photoelectric conversion element and the connector.

21. The method of claim 20, wherein the recessed portion and the focusing layer are formed using an imprint process or a photolithography process.

22. The method of claim 19, wherein the photoelectric conversion element occupies less than or equal to 30% of an area of the substrate.

23. The method of claim 19, wherein the photoelectric conversion element is formed using a photolithography process.
